(19) United States
(12) Patent Application Publication
(10) Pub. No.: US 2022/0317167 A1
(43) Pub. Date: Oct. 6, 2022

(54) METHOD FOR MEASURING AND DISPLAYING THE AUDIO SIGNAL/NOISE RATIO

(71) Applicant: ELENOS S.R.L., Poggio Renation (IT)

(72) Inventor: Leonardo Busi, Poggio Renatico (IT)

(21) Appl. No.: 17/642,682

(22) PCT Filed: Sep. 11, 2020
(86) PCT No.: PCT/IB2020/058469

§ 371 Date: Mar. 12, 2022

(30) Foreign Application Priority Data
Sep. 13, 2019 (IT) 102019000016328

(51) Int. Cl. G01R 23/18; G01R 23/20; G01R 13/02

(52) U.S. Cl. CPC G01R 23/18; G01R 23/20; G01R 13/0227

(57) ABSTRACT

The method allows the measurement of the audio signal-to-noise ratio, without having to interrupt the transmission to make the measurements. The method comprises: taking the audio signal processed by the system in a frequency hand (ΔF) for a predefined 5 measurement time period (T1); Fast Fourier Transform the sampled audio signal to obtain a signal power spectrum for the entire frequency band (ΔF); for each frequency (F), detect and store the maximum (PMax) and minimum (PMin) power values relating to each frequency considered with operations of “MaxHold” and “MinHold”, to obtain 10 corresponding sequences, respectively of maximum power (CMax) and minimum power (Cmin) of the audio signal; for each frequency (F), obtain the signal/audio noise ratio (S/N) of the signal as a function of the corresponding values of said sequences (CMax) and (CMin). 15

### BACKGROUND ART

The present invention belongs to the technical sector relating to radio frequency diffusion systems (“Broadcasting”) of signals, for example of radio or television signals and, more precisely, the audio signal, or the audio part of the signal in the case of television broadcasting, transmitted by such systems.

In particular, the invention relates to a method for measuring and displaying the audio signal/noise ratio of a radio program, or the audio channel of a television program.

The signal-to-noise ratio in an audio transmission measures the ratio between the power of the useful signal and the power of the overall noise emitted by the transmission system, and is a parameter of fundamental importance in evaluating the quality of an audio transmission.

The noise associated with an audio transmission is usually given by the sum of two components: the first is the ambient noise, ie that present in the environment in which the recording is made; the second is the system noise, that is the noise introduced by the components of the audio signal acquisition and processing chain, up to its emission in the antenna. The noise sources can be of a thermal nature, that is associated with the motion of the charge carriers in the conductors and in the active components of the system; they can be generated by interference between different transmitted signals; or caused by electrical phenomena generated in the atmosphere. In any case it is a spurious signal of a random nature, which can become annoying if it is not kept below audibility levels.

In every radio and television transmission system, the audio signal/noise ratio is regularly monitored to ensure the quality of the audio signal sent to the antenna.

Conventional monitoring methods generally provide for the on-line insertion of test signals, temporally offset from each other. In particular, a reference signal having known characteristics and a mute signal are introduced in sequence, and their output powers are measured. The ratio of the measured powers gives the signal-to-noise ratio for that line.

Measurements can provide an instant signal-to-noise ratio, a ratio given by the average of the measurements over time, and can be made with reference signals of different frequencies, to provide information on the signal-to-noise ratio in different portions of the audio band.

In any case, in order to carry out the measurements described above it is necessary that the transmission system is not operational, in order to be able to insert known signals and perform calculations on them. This constitutes a significant drawback when it is necessary to monitor the quality of an audio transmission in real time, perhaps of a channel active 24 hours a day, as to obtain the measurements it is necessary to interrupt the transmission for a time that depends on the type and accuracy of the measurements made.

This is usually considered unacceptable, or in any case accepted with great difficulty by those responsible for radio and television broadcasts.

### SUMMARY OF THE INVENTION

The object of the present invention is to propose a method for real-time measurement of the audio signal/noise ratio in a radio and television broadcasting capable of providing precise and continuous information without disturbing the transmission itself and without having to interrupt it during measurements.

Another object of the invention is to propose a method for real-time display of the audio signal/noise ratio in a radio and television broadcast measured as described above.

The aforementioned purposes, and others besides, are entirely achieved, in accordance with the content of the claims, by means of a method that allows the measurement and display of the audio signal/noise ratio in a system for radio frequency broadcasting of audio and audio signals./video, without interrupting the transmission to take measurements. The system includes sections for the acquisition of an audio signal, for the analog and/or digital processing of the signal, for the emission of the same in the antenna and for the reception and decoding of the signal.

The method comprises the following operational steps: taking the audio signal processed by the system in a frequency band for a predefined measurement time period; subjecting the picked up audio signal to an FFT (Fast Fourier Transform) operation, to obtain, instant by instant and for the measurement time period, a signal power spectrum for the entire frequency band considered; for each frequency belonging to the frequency band and for the entire measurement time, detect and store the maximum and minimum power values relating to each frequency considered with “MaxHold” and “MinHold” operations, to obtain corresponding sequences, respectively of maximum and minimum power of the audio signal; for each frequency, obtain the signal/audio noise ratio of the signal as a function of the corresponding values of said sequences of maximum and minimum power.

### BRIEF DESCRIPTION OF THE DRAWINGS

The features of the invention will be evident from the following description of a preferred, although not exclusive, embodiment, in accordance with the claims and with the aid of the attached drawing tables, in which:

FIG. 1 illustrates a block diagram of a possible configuration of a system for radio frequency diffusion of audio signals, to which the method according to the invention is applied;

FIG. 2 illustrates a possible display of the maximum and minimum power locus curves in the measurement frequency band.

### DESCRIPTION OF EMBODIMENTS OF THE INVENTION

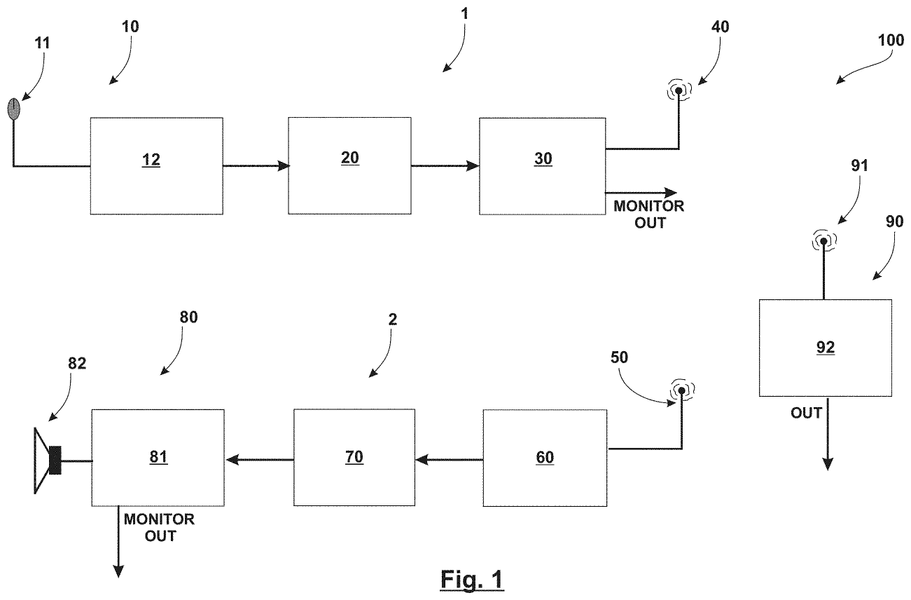

With reference to FIG. 1, reference numeral 100 indicates, as a whole, a system for the broadcasting of audio signals, which may also include means for the radio-frequency broadcasting of video signals. As far as the present invention is concerned, however, in the latter case reference will be made to the audio section of the system.

The system 100, according to known techniques, can acquire and process an audio signal using both analog and digital technologies.

In a minimal and extremely simplified description for functional blocks, useful only for the purposes of describing the method according to the invention, the system 100 provides a transmitting section 1 and one or more receiving sections 2.

The transmitting section 1 comprises acquisition and encoding means 10 of an audio signal produced in a recording environment, comprising at least one microphone 11 and a preamplifier-encoder apparatus 12. Other known audio inputs of various kinds can also be connected to the latter.

Downstream of the preamplifier-encoder apparatus 12 there is an RF modulator apparatus 20, adapted to convert the low frequency audio signal into a radio frequency signal, suitably modulated by the audio signal.

Connected to this latter apparatus is an RF power amplifier 30, which in turn supplies the amplified RF signal to a transmitting antenna 40, for broadcasting the signal in the air.

Each of the receiving sections 2 comprises, in a substantially mirrored way, a receiving antenna 50, connected to an RF receiver apparatus 60. The latter is connected to a demodulator/decoder apparatus 70, which returns the audio signal in low frequency, towards a BF (low frequency) 80 output device.

The latter comprises a power amplifier BF 81, to which one or more audio reproduction devices 82 are connected, which may include speakers, audio headphones or the like.

As already mentioned above, each section of the system 100 introduces its own noise component into the audio channel, which adds to the useful signal and the noise already present, which reduces the signal/noise ratio (Y/N) and can also deteriorate significantly the overall signal, reducing its quality. During a high quality audio transmission it is therefore important to monitor the signal/noise ratio as frequently as possible, in order to intervene in the event of exceeding the minimum thresholds considered acceptable.

According to the invention, the method for measuring and displaying the audio signal/noise ratio in the system 100 provides for the continuous or periodic execution of the measurement of the S/N ratio of the audio signal without having to interrupt the audio information flow of the channel.

The method can be advantageously carried out using various apparatuses or groups of apparatuses, known to them, the structure and operation of which are well known by a technician of average experience.

The method provides for the cyclic execution, according to predetermined periods, of a sequence of procedural steps, the first of which involves taking the signal from the audio channel which is to be monitored. The signal is preferably picked up in correspondence with a final processing stage of the system 100 or of a section, transmitter 1 or receiver 2, in such a way as to obtain a measure indicative of the goodness of the diffused audio signal, or of the received one.

In this regard, according to possible different requirements, the signal can be picked up for example at the RF power amplifier 30 of the transmitting section 1, preferably from a monitor output of the same (monitor out); at the power amplifier BF 81 of the receiving section 2, preferably from a monitor output of the same; or “in the field”, downstream of the transmitting antenna 40 of the transmitting section 1, by means of a monitoring receiving apparatus 90 which comprises a monitoring antenna 91 and a receiver 92 capable of receiving, demodulating and possibly decoding the audio signal RF, to obtain the BF signal to be analyzed and make it available at the output for sampling.

A single measurement cycle, or T1 measurement time, can have a variable overall duration, depending on specific needs. Basically, a shorter cycle duration means a higher updating frequency of the values of the S/N ratio, with a lower accuracy of the measurement. Quite specularly, a longer T1 measurement time results in higher measurement accuracy, at the expense of the measurement update rate. Typically, but not limitedly, T1 measurement times can be had between 1 second and 5 minutes.

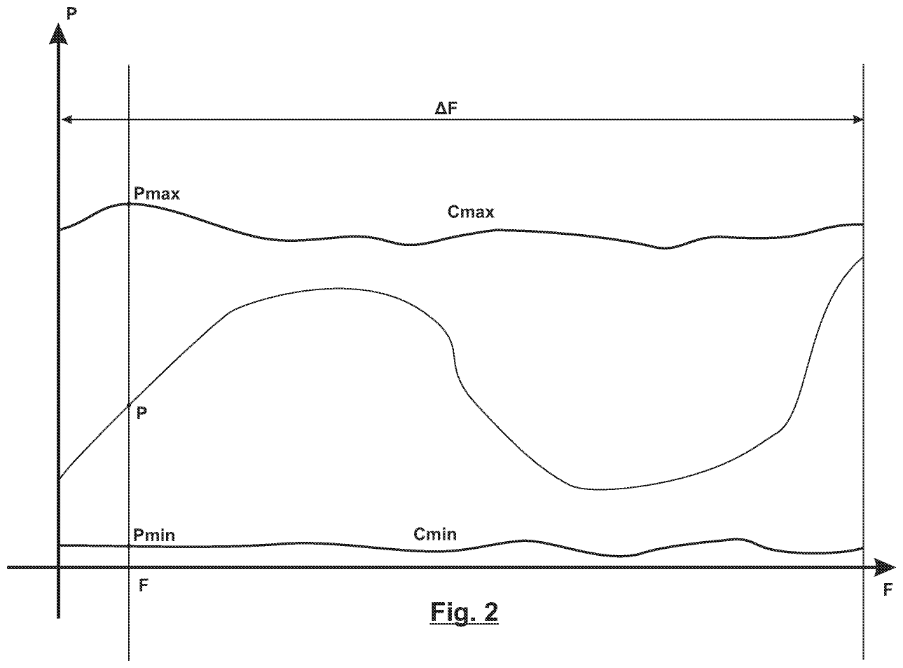

The picked up audio signal (see FIG. 2) comprises an audio frequency band ΔF which generally belongs to the overall audio band of the system, and preferably contains it all; the signal processing, as will be better detailed in the following, can also be carried out on a higher frequency band (indicatively, for a quality audio transmission, the picked up band can be between 30 and 15,000 Hz).

The next step of the method according to the invention comprises the application to the taken audio signal of an FFT (Fast Fourier Transform) operation, intended to bring the information relating to the signal from the time domain to that of the frequencies. Therefore, for each instant and for the entire measurement time period T1, a signal power spectrum is obtained for the entire frequency band ΔF considered.

In a subsequent phase of the method, for each frequency F belonging to the frequency band ΔF analyzed, and for the entire measurement time T1 chosen, the maximum power values PMax and minimum PMin are detected and stored, with “MaxHold” and “MinHold” operations. For the entire spectrum of frequencies ΔF, therefore, sequences of maximum power value CMax and minimum CMin are obtained; the values for each single frequency F are updated during the measurement time T1 when new maximum or minimum of the instantaneous power is reached.

For each frequency F the signal/noise ratio S/N is then obtained as a function of the corresponding maximum and minimum values in the aforementioned sequences CMax and CMin, for example as the difference of the respective values expressed in db.

Since the values in the CMax and CMin sequences represent the extreme values reached by the power readings, they can be continuously updated during the T1 measurement time period. The latter must therefore be chosen in such a way as to allow the aforementioned sequences to stabilize sufficiently. Higher T1 periods ensure greater stability and accuracy of the measurement.

The result of the measurement operations, i.e. the values of the sequences of maximum power CMax and minimum power CMin, and the values of the signal/noise ratio S/N over the entire spectrum ΔF considered, is then made available to a user, in the forms deemed most convenient.

The result can, for example, be made available in table format, to allow subsequent processing, or it can be directly subjected to a graphic processing and converted into corresponding curves on a Cartesian reference system (FIG. 2) and displayed on a monitor, in in order to provide immediate information on the power values of the signal and its quality in terms of S/N ratio.

The values of the sequences of maximum power CMax and minimum CMin relating to each frequency can also be subjected, before their display, to weighing operations, for example as a function of the sensitivity of the human ear in that specific frequency.

The method according to the invention is applied in a similar way in the case of a stereo audio signal. In this case there is a preliminary phase of separation and decoding of the right and left channels of the signal; the phases of calculating the FFT (“Fast Fourier Transform”), storing the maximum power values PMax and minimum PMin, obtaining the corresponding CMax and CMin sequences and obtaining the audio signal/noise ratio values for each mentioned F frequency considered, are made separately for the left and right channels of the stereo signal.

Furthermore, sequences of maximum power values CMax and minimum CMin can be advantageously generated and the corresponding values of the audio signal/noise ratio obtained also for the superimposition of the right and left signal channels.

The results obtained for both channels can be made available both in tabular and graphical form, and displayed on a monitor, as well as for the results obtained for the single channel audio signal.

The method of the invention can also provide for a comparison step of at least one of the maximum power PMax and minimum power PMin values inserted in the sequences of maximum power CMax and minimum power CMin, and of the audio signal/noise ratio S/N, with respective predefined threshold values. If the aforementioned predefined threshold values are exceeded, corresponding alarm information can be sent to a user, local or remote, to allow corrective action to be taken.

In order to ensure the perfect quality of the measurement, known techniques known as SDR (Software Defined Radio) are preferably used in carrying out the method according to the invention. These are fully digitized audio signal processing techniques.

In this case the conversion of the signal from analog to digital takes place immediately after the signal has been entered into the hardware system responsible for carrying out the processing operations, using an A/D converter (Analog-Digital) with at least 16 bits, in order to guarantee a very high precision and a completely transparent operation from the point of view of the introduction of signal quality reduction factors.

In this phase, a band of the digitized signal wider than that of the signal to be analyzed is treated, again digitally within the hardware, by a processor made with FPGA (Field Programmable Data Array) technology which sends it to the software of a personal computer, via a standard connection, such as USB.

The computer software processes the band to be analyzed with appropriate mathematical algorithms that allow, in near real time (typical delays of the order of 200 ms) the filtering, demodulation and decoding of the transmitted radio signal. With the exception of the first A/D conversion phase, the radio is fully implemented using software algorithms.

The software operations that are carried out are translation and filtering of the signal band, demodulation and filtering according to the modulation standard adopted, decoding and filtering if any particular coding exists.

The software then displays and analyzes the signal during the various passages on various screens.

The implementation of the method according to the invention described above makes it possible to advantageously obtain substantially continuous monitoring of the audio signal/noise ratio of a broadcast transmission, for example a radio or radio-television transmission, without absolutely having to cause interruption to the transmission itself, and in an absolutely transparent way for those responsible for the production of the content and the technical managers of the diffusion.

Another advantage produced by the present method is given by the possibility of visually checking, instant by instant, the situation of the audio signal/noise ratio of a transmission being broadcast in the entire signal emission band.

Another advantage is given by the possibility of producing fully automatic alarm information in correspondence with significant drops in the quality of the transmitted audio signal.

However, it is understood that the foregoing has an exemplary and non-limiting value, therefore any detailed changes are considered as of now falling within the protective scope defined by the claims below.

1) Method for measuring an audio signal/noise ratio in a system for radio frequency broadcasting of audio signals or audio and video signals, said system (100) comprising sections for the acquisition of an audio signal, for the analog and/or digital processing of said audio signal for providing a processed signal for transmission of the processed signal as a transmitted signal via a transmitting antenna and of reception of the transmitted signal as a received signal via a receiving antenna and decoding of the received signal; said method comprising:
transmitting the processed signal in a frequency band (ΔF) belonging to an overall audio band of the system (100) and for a predefined measurement time period (T1);
subjecting at least one of said processed signal, said transmitted signal, or said received signal a to a Fast Fourier Transform (FFT) operation, to obtain a plurality of measurements, instant by instant and for said measurement time period (T1), comprising a power spectrum of said at least one of said processed signal, said transmitted signal, or said received signal for the frequency band (ΔF);
for each selected frequency (F) of a plurality of selected frequencies for consideration belonging to said frequency band (ΔF) and for the predefined measurement time period (T1), detecting and storing maximum (PMax) and minimum (PMin) power values relating to each selected frequency considered with maximum detection (MaxHold) and minimum detection (MinHold) and storage operations, to obtain corresponding sequences of maximum power (CMax) and minimum power (Cmin) measurements respectively of said at least one of said processed signal, said transmitted signal, or said received signal;
for each said selected frequency (F), obtaining the audio signal/noise ratio (S/N) of said at least one of said processed signal, said transmitted signal, or said received signal as a function of corresponding values of said sequences of maximum power (CMax) and minimum power (CMin); said measurement time period (T1) allowing for a substantial stabilization of said sequences of maximum power (CMax) and minimum power (CMin).

2) The method according to claim 1, wherein said Fast Fourier Transform (FFT) operation is carried out on said processed signal at a final output of a transmitting section (1) of the system (100) for broadcasting of audio signals or audio and video signals.

3) The method according to claim 2, wherein said final output consists a monitor output of the transmitting section (1).

4) The method according to claim 1, wherein said Fast Fourier Transform (FFT) operation is carried out on said transmitted signal downstream of the transmitting antenna (40) by a receiver apparatus (90) for acquiring the transmitted signal in different conditions of intensity and quality of the transmitted signal.

5) The method according to claim 1, wherein said Fast Fourier Transform (FFT) operation is carried out on said received signal at a final output of a receiving section (2) of the system (100), immediately before providing said received signal to one or more audio reproduction devices (82).

6) The method according to claim 1, wherein said frequency band (ΔF) is greater than or equal to the bandwidth of the system (100).

7) The method according to claim 1, wherein said measurement time period (T1) is between 1 second and 5 minutes.

8) The method according to claim 1, wherein for each selected frequency (F) of the band (ΔF) considered, each of said power values, respectively maximum (PMax) and minimum (PMin) is further subjected to weighing operations as a function of human ear sensitivity for a corresponding frequency.

9) The method according to claim 1, wherein said audio signal is a stereo signal having right and left channels, that a preliminary phase of separation of the right and left channels is provided, and that said Fast Fourier Transform (FFT) operation, storage of the maximum (PMax) and minimum (PMin) power values, obtaining the corresponding sequences (CMax) and (CMin) and obtaining the audio signal/noise ratio values (S/N) for each selected frequency (F) considered, are performed separately for the left and right channels of said stereo signal.

10) The method according to claim 9, wherein sequences of maximum (CMax) and minimum (CMin) power values are also generated and the corresponding values of audio signal/noise ratio (S/N) obtained also for a superposition of the left and right channels of said stereo signal.

11) The method according to claim 1, further comprising providing said sequences of maximum (CMax) and minimum (CMin) power values, and of audio signal/noise ratio (S/N), in the form of tables.

12) The method according to claim 1, further comprising providing said sequences of maximum (CMax) and minimum (CMin) power values, and of audio signal/noise ratio (S/N), in the form of viewable curves.

13) The method according to claim 12, further comprising display of at least one of said viewable curves on a monitor.

14) The method according to claim 1, further comprising comparing at least one of said values of maximum power (PMax), minimum power (PMin) and audio signal/noise ratio (S/N) with respective thresholds, and providing corresponding alarm information in case of exceeding a threshold.

15) A method for estimating a signal to noise ratio (SNR) of an audio signal before, during, or after broadcast through a radio frequency channel, comprising:
taking, at a plurality of instances within a measurement period a Fast Fourier Transform (FFT) of the audio signal,
recording, for each of a plurality of frequencies, and for each FFT, minimum and maximum spectral power values, and
forming a measure of the channel SNR as the ratio of each pair of recorded maximum and minimum spectral power values.
